(19) United States
(12) Patent Application Publication
(10) Pub. No.: US 2026/0047429 A1
(43) Pub. Date: Feb. 12, 2026

(54) ELECTRONIC DEVICE

(71) Applicant: InnoLux Corporation, Miao-Li County (TW)

(72) Inventors: Wei-Yuan CHENG, Miao-Li County (TW); Chieh-Chen FU, Miao-Li County (TW); Jeng-Nan LIN, Miao-Li County (TW); Ju-Li WANG, Miao-Li County (TW)

(21) Appl. No.: 19/257,863

(22) Filed: Jul. 2, 2025

Related U.S. Application Data
(60) Provisional application No. 63/680,658, filed on Aug. 8, 2024.

(30) Foreign Application Priority Data
Mar. 18, 2025 (CN) 202510318446.7

(51) Int. Cl. H01L 23/367; H01L 23/00; H01L 23/31; H01L 23/498

(52) U.S. Cl. CPC H01L 23/3675; H01L 23/3677; H01L 24/16; H01L 24/32; H01L 24/73; H01L 23/3128; H01L 23/49816; H01L 2224/16227; H01L 2224/32225; H01L 2224/73204; H01L 2224/73253

(57) ABSTRACT

An electronic device is provided. The electronic device includes an electronic unit and a circuit structure. The circuit structure is electrically connected to the electronic unit. The circuit structure includes a first conductive layer, a first insulating layer and a first heat dissipation element. The first insulating layer is disposed between the first conductive layer and the electronic unit. The first heat dissipation element is in contact with the first conductive layer. Moreover, a heat transfer coefficient of the first dissipation element is greater than a heat transfer coefficient of the first insulating layer and less than a heat transfer coefficient of the first conductive layer.

### CROSS REFERENCE TO RELATED APPLICATIONS

This application claims the benefit of China Application No. 202510318446.7, filed Mar. 18, 2025, which claims the benefit of provisional Application No. 63/680,658 filed Aug. 8, 2024, the entirety of which are incorporated by reference herein.

### BACKGROUND

### Technical Field

The present disclosure is related to an electronic device, and in particular it is related to an electronic device with improved heat dissipation performance.

### Description of the Related Art

Packaging technology can increase the integration density of electronic components (e.g., transistors, diodes, resistors, capacitors, etc.) in a given area, and has been widely used in the production and manufacturing of electronic devices in recent years. As the packaging size of semiconductors becomes smaller, the reliability requirements for chip manufacturing and packaging technology are getting higher.

The adoption of advanced packaging technologies such as 2.5D or 3D packaging involves stacking chips and packaging them on a substrate., thereby reducing the area occupied by the chips and reducing the cost and energy consumption associated with driving the chips. Electronic devices usually use a redistribution layer (RDL) to redistribute routes or increase the fan-out area of the routes. For example, the contact positions of the integrated circuit (IC) are changed through a metal wiring process and a bumping process so that the integrated circuit can be applied to different component modules.

However, when multiple modules or systems are simultaneously connected to the same redistribution structure substrate, the heat energy generated by each module or system is likely to be accumulated on the substrate in large quantities, thereby affecting the performance of the electronic device. In order to further enhance the performance of electronic devices, developing a structural design that can improve the heat dissipation performance of electronic devices is still one of the current research topics in the industry.

### SUMMARY

In accordance with some embodiments of the present disclosure, an electronic device is provided. The electronic device includes an electronic unit and a circuit structure. The circuit structure is electrically connected to the electronic unit. The circuit structure includes a first conductive layer, a first insulating layer and a first heat dissipation element. The first insulating layer is disposed between the first conductive layer and the electronic unit. The first heat dissipation element is in contact with the first conductive layer. Moreover, a heat transfer coefficient of the first dissipation element is greater than a heat transfer coefficient of the first insulating layer and less than a heat transfer coefficient of the first conductive layer.

To make the features or advantages disclosed herein more clearly understandable, a detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a cross-sectional diagram of an electronic device in accordance with some embodiments of the present disclosure;

FIG. 2 is a cross-sectional diagram of an electronic device in accordance with some embodiments of the present disclosure;

FIG. 3 is a cross-sectional diagram of an electronic device in accordance with some embodiments of the present disclosure;

FIG. 4 is a cross-sectional diagram of an electronic device in accordance with some embodiments of the present disclosure;

FIG. 5 is a cross-sectional diagram of an electronic device in accordance with some embodiments of the present disclosure;

FIG. 6 is a cross-sectional diagram of an electronic device in accordance with some embodiments of the present disclosure;

FIG. 7 is a cross-sectional diagram of an electronic device in accordance with some embodiments of the present disclosure;

FIG. 8 is a cross-sectional diagram of an electronic device in accordance with some embodiments of the present disclosure.

### DETAILED DESCRIPTION

The electronic device according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

In accordance with the embodiments of the present disclosure, the thickness, length and width can be measured by using an optical microscope (OM), and the thickness or width can be measured by using a cross-sectional image in an electron microscope, but it is not limited thereto. The surface roughness can be measured by using a scanning electron microscope (SEM) or a transmission electron microscope (TEM) to observe the surface undulations at the same appropriate magnification, and the undulations can be compared per unit length (e.g., 10 μm). Appropriate magnification means that at least one surface being observable under this magnification and field of view showing at least 10 peaks or troughs of roughness, enabling observation and analysis of either the peak-to-valley roughness (Rt) or the mean roughness [symbol] Ra [symbol] .

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiments of the present disclosure, an electronic device is provided that includes a specific configuration of heat dissipation element, which can enhance the heat dissipation performance of the electronic device (for example, an electronic device having a redistribution structure), thereby improving the reliability and performance of the electronic device.

In accordance with the embodiments of the present disclosure, the electronic device can be applied to a power module, a semiconductor packaging device, a display device, a light-emitting device, a backlight device, an antenna device, a touch device, a sensing device, a wearable device, an automotive device, a battery device or a tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy or ultrasonic waves, but it is not limited thereto. Furthermore, the electronic device may include, for example, liquid crystals, quantum dots (QDs), fluorescence, phosphorescence, another suitable material, or a combination thereof. The electronic device may include electronic components, and the electronic components may include passive components and active components, such as capacitors, resistors, inductors, diodes, transistors, etc. The diode may include a light-emitting diode or a photodiode. The light-emitting diode may include, for example, an organic light-emitting diode (OLED), a mini light-emitting diode (mini LED), a micro-light-emitting diode (micro LED) or a quantum dot light-emitting diode (QD LED), but it is not limited thereto. In accordance with some embodiments, the electronic device may include a panel and/or a backlight module. The panel may include, for example, a liquid-crystal panel or other self-luminous panel, but it is not limited thereto. The tiled device may be, for example, a display tiled device or an antenna tiled device, but it is not limited thereto. It should be understood that the electronic device can be any permutation and combination of the above, but it is not limited thereto.

Furthermore, in accordance with the embodiments of the present disclosure, the electronic device provided can be applied to a packaging structure. The packaging structure may include a system on package (SoC), a system in package (SiP), a chip on wafer on substrate (CoWoS) package, a system on integrated chip (SoIC) package, an antenna in package (AiP), a co-packaged optics (CPO), a micro electro mechanical system (MEMS) or a combination thereof, but it is not limited thereto.

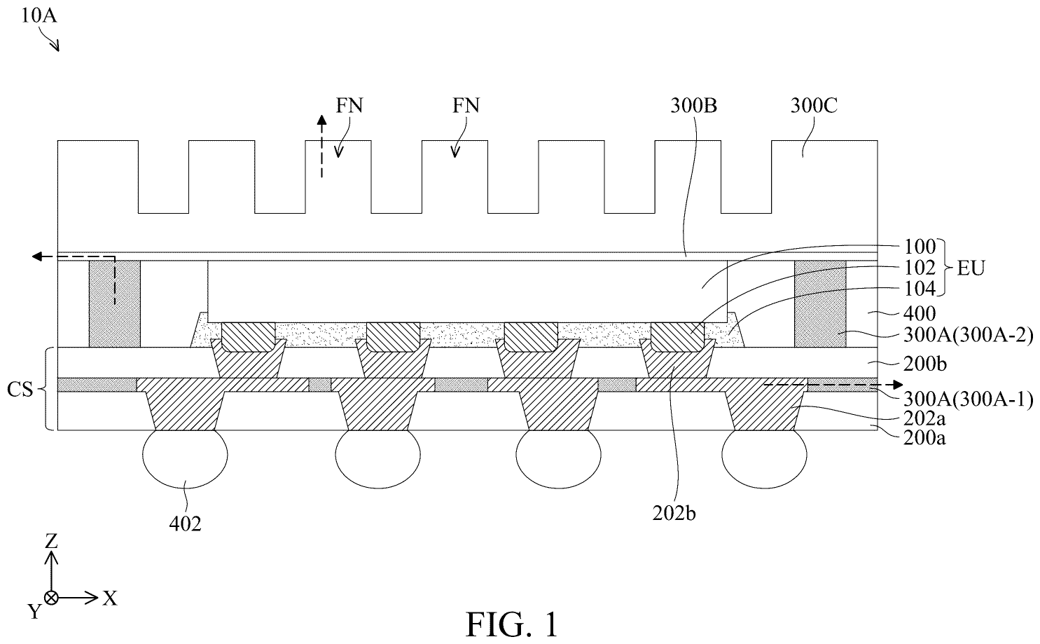

Please refer to FIG. 1, which is a cross-sectional diagram of an electronic device 10A in accordance with some embodiments of the present disclosure. It should be understood that, for clarity of explanation, some components of the electronic device 10A may be omitted in the drawings, and only some components are schematically illustrated. In accordance with some embodiments, additional features may be added to the electronic device 10A described below.

Referring to FIG. 1, the electronic device 10A includes an electronic unit EU and a circuit structure CS, and the circuit structure CS is electrically connected to the electronic unit EU. In accordance with some embodiments, the electronic unit EU may include a chip 100, a conducting pad 102, and an insulating layer 104, but it is not limited thereto. The conducting pad 102 may be disposed on one side of the chip 100. The chip 100 may be electrically connected to the conducting pad 102. The chip 100 may be electrically connected to the circuit structure CS through the conducting pad 102. The insulating layer 104 may contact the chip 100 and the conducting pad 102. In accordance with some embodiments, the insulating layer 104 may be disposed between the chip 100 and the circuit structure CS, and the insulating layer 104 may surround the conducting pad 102.

In accordance with some embodiments, the chip 100 may include, for example, a known-good die (KGD), an integrated circuit chip (IC), a surface mount device (SMD), a diode chip, an antenna unit, a sensor, a structure of a semiconductor-related process, or a structure of a semiconductor-related process disposed on a substrate (such as polyimide, glass, silicon substrate or another suitable substrate material), or another suitable electronic component, but it is not limited thereto. Specifically, in accordance with some embodiments, the electronic unit EU may include a system on chip, a dynamic random-access memory, a high-bandwidth memory, a photonic integrated circuit (PIC), an application-specific integrated circuit, or another logic integrated circuit.

In detail, the electronic unit EU may include at least one conducting pad 102. In accordance with some embodiments, in the cross-sectional view, the widths of the conducting pads 102 may be the same or different. In accordance with some embodiments, the conducting pad 102 may include a conductive material, such as a metallic conductive material. In accordance with some embodiments, the conducting pad 102 may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material, or a combination thereof, but it is not limited thereto. Furthermore, according to the embodiments of the present disclosure, the aforementioned width may be the maximum width of the conducting pad 102 perpendicular to the normal direction of the chip 100.

In accordance with some embodiments, the insulating layer 104 may be an encapsulating material or an underfill, but it is not limited thereto. In accordance with some embodiments, the insulating layer 104 may include molding compound, an epoxy resin, another suitable encapsulating material, or a combination thereof, but it is not limited thereto.

In accordance with some embodiments, the circuit structure CS may include a conductive layer 202a, a conductive layer 202b, an insulating layer 200a, an insulating layer 200b and a first heat dissipation element 300A (also labeled as 300A-1 for the convenience of subsequent description). The insulating layer 200b may be disposed on the insulating layer 200a. The conductive layer 202b may be disposed on the conductive layer 202a. The insulating layer 200b may be disposed between the conductive layer 202a and the electronic unit EU. In accordance with some embodiments, the conductive layer 202b may serve as a contact pad, and the conducting pad 102 of the electronic unit EU may be electrically connected to the circuit structure CS through the conductive layer 202b.

Furthermore, the circuit structure CS can serve as a redistribution layer (RDL) of the electronic device 10A. The circuit structure CS includes at least one conductive layer (e.g., conductive layer 202a, conductive layer 202b) and at least one insulating layer (e.g., insulating layer 200a, insulating layer 200b), which can enable the route of the electronic device to be redistributed and/or further increase the route fan-out area, or different electronic components can be electrically connected to each other through the circuit structure CS. The insulating layers and the conductive layers may be stacked in a direction parallel to the normal direction of the electronic unit EU. The redistribution structure may extend a connection to a wider pitch or reroute a connection to another connection having a different pitch, and/or the redistribution layer may serve as a substrate for electrical interface routing between two connections. For example, the pitch between two adjacent contact pads at one end of the redistribution structure contacting with the electronic component may be less than or equal to the pitch between two adjacent contact pads at one end of the redistribution structure away from the electronic component. Therefore, the redistribution structure can adjust the route fan-out condition or electrically connect a circuit structure/electronic component with a first pitch to a circuit structure/electronic component with a second pitch, but it is not limited thereto. Moreover, the step of forming a redistribution layer may include providing a stack of at least one conductive layer and at least one insulating layer, and the method of forming the redistribution layer may include processes such as photolithography, etching, surface treatment, laser, electroplating, chemical plating, deposition, and atomic layer deposition. The surface treatment may include roughening or activating the surface of the insulating layer or the conductive layer to enhance the bonding ability of the insulating layer or the conductive layer. For example, the bonding force between the insulating layer and the subsequent film layer may be enhanced by enhancing the surface roughness. In accordance with some embodiments, when the redistribution structure has a plurality of insulating layers, coefficient of thermal expansions of the insulating layers may be the same or different. Further, in accordance with some embodiments, when the coefficient of thermal expansions of the insulating layers are different, the coefficient of thermal expansion of the insulating layer close to the electronic unit EU may be less than the coefficient of thermal expansion of the insulating layer away from the electronic unit EU.

Specifically, in accordance with some embodiments, the materials of the conductive layer 202a and the conductive layer 202b may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material or a combination thereof, but they are is not limited thereto. Furthermore, the material of the conductive layer 202a may be the same as or different from that of the conductive layer 202b.

In accordance with some embodiments, the materials of the insulating layer 200a and the insulating layer 200b may include inorganic materials, organic materials, or a combination thereof, but they are not limited thereto. In accordance with some embodiments, the inorganic material may include silicon nitride, silicon oxide, silicon oxynitride, glass, another suitable insulating material, or a combination thereof, but it is not limited thereto. In accordance with some embodiments, the organic material may include polyimide (PI), photosensitive polyimide (PSPI), polybenzoxazole (PBO), benzocyclobutene (BCB), epoxy, Ajinomoto Build-up Film (ABF), solder resist material, another suitable insulating material or a combination thereof, but it is not limited thereto. As mentioned above, the material of the insulating layer 200a may be the same as or different from that of the insulating layer 200b.

In addition, in accordance with some embodiments, the first heat dissipation element 300A may be disposed in the circuit structure CS, and the first heat dissipation element 300A may contact the conductive layer 202a. For example, in the cross-sectional view, the first heat dissipation element 300A may be disposed in the gap between the patterned portions of the conductive layer 202a and contact the side of the conductive layer 202a. In accordance with some embodiments, the upper surface and/or the lower surface of the first heat dissipation element 300A may be substantially aligned or coplanar with the upper surface and/or the lower surface of the conductive layer 202a, but it is not limited thereto. Furthermore, in accordance with some embodiments, the first heat dissipation element 300A may also contact the insulating layer 200a and the insulating layer 200b. In particular, the heat transfer coefficient of the first heat dissipation element 300A is greater than the heat transfer coefficient of the insulating layer 200b and less than the heat transfer coefficient of the conductive layer 202a. In accordance with some embodiments, the coefficient of thermal expansion (CTE) of the first heat dissipation element 300A is greater than the coefficient of thermal expansion of the insulating layer 200b and less than the coefficient of thermal expansion of the conductive layer 202a.

In detail, in accordance with some embodiments, the heat transfer coefficient of the first heat dissipation element 300A may be greater than or equal to 3 W/mK and less than or equal to 50 W/mK (i.e. 3 W/mK≤heat transfer coefficient≤50 W/mK), for example, 5 W/mK, 10 W/mK, 15 W/mK, 20 W/mK, 25 W/mK, 30 W/mK, 35 W/mK, 40 W/mK or 45 W/mK, but it is not limited thereto. In accordance with some embodiments, the coefficient of thermal expansion of the first heat dissipation element 300A may be greater than or equal to 5 ppm/° C. and less than or equal to 40 ppm/° C. (i.e. 5 ppm/° C.≤coefficient of thermal expansion≤40 ppm/° C.). For example, in the embodiment shown in FIG. 1, the coefficient of thermal expansion of the first heat dissipation element 300A (300A-1) may be greater than or equal to 10 ppm/° C. and less than or equal to 40 ppm/° C., for example, 15 ppm/° C., 20 ppm/° C., 25 ppm/° C., 30 ppm/° C. or 35 ppm/° C., but it is not limited thereto. Furthermore, the ratio of the coefficient of thermal expansion of the first heat dissipation element 300A (300A-1) to the coefficient of thermal expansion of the insulating layer 200a or the insulating layer 200b may be between 0.6 and 4 (i.e. 0.6≤coefficient of thermal expansion of the first heat dissipation element 300A-1/coefficient of thermal expansion of the insulating layer 200a≤4, or 0.6≤coefficient of thermal expansion of the first heat dissipation element 300A-1 / coefficient of thermal expansion of the insulating layer 200b≤4), for example, 0.7, 0.8, 0.9, 1, 1.1, 1.2, 1.3,1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8 or 3.9, but it is not limited thereto.

It is noted that, with the configuration of the aforementioned first heat dissipation element 300A, the horizontal heat conduction capability of the electronic device or circuit structure CS can be significantly improved. Please refer to the heat dissipation direction indicated by the dotted arrow in FIG. 1.

In accordance with some embodiments, the base material of the first heat dissipation element 300A may include photosensitive polyimide (PSPI), epoxy, another suitable polymer material or a combination thereof, but it is not limited thereto. Furthermore, the first heat dissipation element 300A may include filler particles. In accordance with some embodiments, the first heat dissipation element 300A may include different types of filler particles, such as filler particles having different heat transfer coefficients. Furthermore, in accordance with some embodiments, the first heat dissipation element 300A may include first filler particles with a relatively small heat transfer coefficient and second filler particles with a relatively large heat transfer coefficient. The aforementioned first filler particles may, for example, include silicon dioxide, aluminum oxide, titanium dioxide or a combination thereof, but it is not limited thereto. The aforementioned second filler particles may, for example, include graphene, silicon carbide, aluminum nitride or a combination thereof, but it is not limited thereto.

In addition, in accordance with some embodiments, the solid content of the first heat dissipation element 300A may be between 20wt % and 90wt % (i.e. 20wt %≤solid content≤90wt %). For example, in the embodiment shown in FIG. 1, the solid content of the first heat dissipation element 300A (300A-1) may be between 20wt % and 60wt %, for example, 30wt %, 35wt %, 40wt %, 45wt %, 50wt % or 55wt %, but it is not limited thereto. In accordance with some embodiments, the particle size of the filler particles of the first heat dissipation element 300A may be between 0.02 mm and 55 mm. For example, in the embodiment shown in FIG. 1, the particle size of the filler particles of the first heat dissipation element 300A (300A-1) may be between 0.02 mm and 30 mm, for example, 0.5 mm, 1 mm, 5 mm, 10 mm, 15 mm, 20 mm or 25 mm, but it is not limited thereto. In particular, filler particles that are within the aforementioned particle size range can provide a complete thermal conductive path. In addition, in accordance with some embodiments, in the first heat dissipation element 300A (300A-1), the ratio of the content of the first filler particles with a relatively small heat transfer coefficient to the content of the second filler particles with a relatively large heat transfer coefficient may be greater than 0 and less than or equal to 0.6 (i.e. 0<content of first filler particles/content of second filler particles≤0.6). For example, in the embodiment shown in FIG. 1, the ratio of the content of the first filler particles to the content of the second filler particles may be greater than or equal to 0.4 and less than or equal to 0.6, such as 0.45, 0.5 or 0.55, but it is not limited thereto. The first filler particles and the second filler particles configured in the aforementioned ratio can enhance the insulation property of the first heat dissipation element 300A and avoid electrical interference to the circuit structure CS.

As shown in FIG. 1, the electronic device 10A may further include an encapsulation layer 400. The encapsulation layer 400 surrounds the electronic unit EU. The encapsulation layer 400 may contact the chip 100, the insulating layer 104, and the insulating layer 200b of the circuit structure CS. The encapsulation layer 400 can reduce the impact of water and oxygen in the external environment on the electronic unit EU. In accordance with some embodiments, the heat transfer coefficient of the first heat dissipation element 300A is less than or equal to the heat transfer coefficient of the encapsulation layer 400. In accordance with some embodiments, the encapsulation layer 400 may include a molding compound, an epoxy resin, another suitable encapsulation material, or a combination thereof, but it is not limited thereto. Furthermore, the material of the encapsulation layer 400 may be the same as or different from the material of the insulating layer 104. In accordance with some embodiments, the encapsulation layer 400 may be formed by a compression molding process, a transfer molding process, or another suitable process. In accordance with some embodiments, the encapsulation layer 400 may be molded in a liquid or semi-liquid state and then cured.

Moreover, in accordance with some embodiments, the electronic device 10A may further include another first heat dissipation element 300A (for convenience of explanation, the first heat dissipation element 300A disposed in the encapsulation layer 400 is also labeled as 300A-2). The first heat dissipation element 300A-2 may be disposed in the encapsulation layer 400 and contact the insulating layer 200b. In accordance with some embodiments, the first heat dissipation element 300A-2 may extend from a top surface to a bottom surface of the encapsulation layer 400. In other words, the first heat dissipation element 300A-2 may penetrate the encapsulation layer 400. The material and function of the first heat dissipation element 300A-2 are the same as or similar to those of the first heat dissipation element 300A-1, and thus are not repeated here.

Furthermore, the heat transfer coefficient of the first heat dissipation element 300A (300A-2) disposed in the encapsulation layer 400 may be greater than or equal to 3 W/mK and less than or equal to 50 W/mK. The coefficient of thermal expansion of (300A-2) may be greater than or equal to 5 ppm/° C. and less than or equal to 40 ppm/° C. (e.g., greater than or equal to 3 ppm/° C. and less than or equal to 15 ppm/° C.), for example, 5 ppm/° C., 8 ppm/° C., or 12 ppm/° C., but it is not limited thereto. Furthermore, the ratio of the coefficient of thermal expansion of the first heat dissipation element 300A (300A-2) to the coefficient of thermal expansion of the insulating layer 200a or the insulating layer 200b may be between 0.6 and 4 (e.g., between 0.8 and 4) (i.e. 0.8≤coefficient of thermal expansion of the first heat dissipation element 300A-2 / coefficient of thermal expansion of the insulating layer 200a≤4, or 0.8≤coefficient of thermal expansion of the first heat dissipation element 300A-2/coefficient of thermal expansion of the insulating layer 200b≤4), for example, may be 0.9, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, 3, 3.1, 3.2, 3.3, 3.4, 3.5, 3.6, 3.7, 3.8 or 3.9, but it is not limited thereto.

In addition, in accordance with some embodiments, the solid content of the first heat dissipation element 300A (300A-2) may be between 20wt% and 90wt% (for example, between 60wt% and 90wt%), for example, 65wt%, 70wt% or 75wt%, but it is not limited thereto. In accordance with some embodiments, the particle size of the filler particles of the first heat dissipation element 300A (300A-2) may be between 0.02 mm and 55 mm (for example, between 0.02 mm and 50 mm), for example, 0.5 mm, 1 mm, 5 mm, 10 mm, 15 mm, 20 mm, 25 mm, 30 mm, 35 mm, 40 mm or 45 mm, but it is not limited thereto. In particular, filler particles that are within the aforementioned particle size range can provide a complete thermal conductive path. In addition, in accordance with some embodiments, in the first heat dissipation element 300A (300A-2), the ratio of the content of the first filler particles with a relatively small heat transfer coefficient to the content of the second filler particles with a relatively large heat transfer coefficient may be greater than 0 and less than or equal to 0.6 (for example, greater than 0.2 and less than or equal to 0.4), for example, it may be 0.25, 0.3 or 0.35, but it is not limited thereto. The first filler particles and the second filler particles configured in the aforementioned ratio can enhance the insulation property of the first heat dissipation element 300A (300A-2) and avoid electrical interference to the circuit structure CS.

In accordance with some embodiments, the electronic device 10A may further include a second heat dissipation element 300B and a third heat dissipation element 300C. The second heat dissipation element 300B may be disposed on the encapsulation layer 400. The electronic unit EU may be disposed between the second heat dissipation element 300B and the circuit structure CS. The third heat dissipation element 300C may be disposed on the second heat dissipation element 300B and have a plurality of fin structures FN. The second heat dissipation element 300B may contact the chip 100, the encapsulation layer 400, and the first heat dissipation element 300A-2 disposed in the encapsulation layer 400. In accordance with some embodiments, the third heat dissipation element 300C may contact the air, and the fin structure FN may increase the surface in contact with the air, thereby improving the heat dissipation effect.

In accordance with some embodiments, the heat transfer coefficient of the second heat dissipation element 300B is greater than the heat transfer coefficient of the first heat dissipation element 300A. In accordance with some embodiments, the heat transfer coefficient of the third heat dissipation element 300C is greater than the heat transfer coefficient of the first heat dissipation element 300A. For example, the heat transfer coefficient of the second heat dissipation element 300B is greater than the heat transfer coefficient of the first heat dissipation element 300A and less than the heat transfer coefficient of the third heat dissipation element 300C. In accordance with some embodiments, the material of the second heat dissipation element 300B may be the same as or similar to that of the first heat dissipation element 300A. In accordance with some embodiments, the material of the third heat dissipation element 300C may include metal (such as copper), graphite, another suitable material, or a combination thereof, but it is not limited thereto.

Furthermore, in accordance with some embodiments, the electronic device 10A may further include a connection element 402, and the connection element 402 may be electrically connected to the conductive layer 202a of the circuit structure CS. In accordance with some embodiments, the connection element 402 may be further electrically connected to an external electronic element. For example, the connection element 402 may be further electrically connected to a printed circuit board (PCB), a chip, a control element or another electronic element (not illustrated), but the present disclosure is not limited thereto.

In accordance with some embodiments, the material of the connection element 402 may include tin, silver, lead-free tin, copper, nickel, gold, another suitable material or a combination thereof, but it is not limited thereto. In accordance with some embodiments, the connection element 402 may be bonded to the conductive layer 202a of the circuit structure CS by a reflow process, a fusion bonding process, a hybrid bonding process, a metal-to-metal bonding process, another suitable process or a combination thereof.

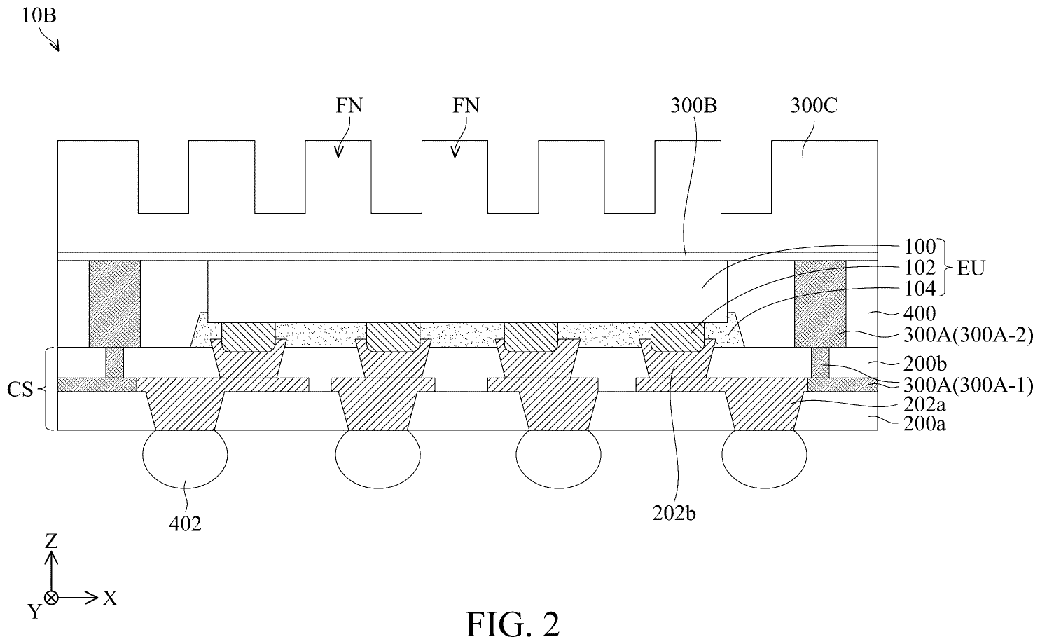

Please refer to FIG. 2, which is a cross-sectional diagram of an electronic device 10B in accordance with some other embodiments of the present disclosure. It should be understood that, for the sake of clarity, some components of the electronic device 10B may be omitted in the drawings, and only some components are schematically illustrated. In accordance with some embodiments, additional features may be added to the electronic device 10B described below. In addition, the components or elements that are the same or similar to those mentioned above will be represented by the same or similar numbers below. Herein, their materials and functions are the same or similar as those mentioned above, and thus will not be repeated in the following description.

The electronic device 10B shown in FIG. 2 is substantially similar to the electronic device 10A. Compared with the electronic device 10A, the first heat dissipation element 300A (300A-1) of the electronic device 10B is not disposed in the gap between the patterned portions of the conductive layer 202a of the circuit structure CS. For example, the first heat dissipation element 300A-1 may be disposed around the conductive layer 202a. Similarly, in this embodiment, the first heat dissipation element 300A-1 is disposed in the circuit structure CS, and the first heat dissipation element 300A-1 is in contact with the conductive layer 202a. The upper surface and/or the lower surface of the first heat dissipation element 300A-1 may be substantially aligned with or coplanar with the upper surface and/or the lower surface of the conductive layer 202a, but it is not limited thereto. Furthermore, the first heat dissipation element 300A-1 is also in contact with the insulating layer 200a and the insulating layer 200b. The heat transfer coefficient of the first heat dissipation element 300A-1 is greater than the heat transfer coefficient of the insulating layer 200b and less than the heat transfer coefficient of the conductive layer 202a. The coefficient of thermal expansion of the first heat dissipation element 300A-1 is greater than the coefficient of thermal expansion of the insulating layer 200b and less than the coefficient of thermal expansion of the conductive layer 202a. Specifically, in this embodiment, the heat transfer coefficient of the first heat dissipation element 300A-1 may be greater than or equal to 3 W/mK and less than or equal to 50 W/mK, and the coefficient of thermal expansion of the first heat dissipation element 300A-1 may be greater than or equal to 10 ppm/° C. and less than or equal to 40 ppm/° C. Furthermore, the ratio of the coefficient of thermal expansion of the first heat dissipation element 300A-1 to the coefficient of thermal expansion of the insulating layer 200a or the insulating layer 200b may be between 0.6 and 4. In addition, in this embodiment, the solid content of the first heat dissipation element 300A-1 may be between 20 wt % and 60 wt %, and the particle size of the filler particles of the first heat dissipation element 300A-1 may be between 0.02 mm and 30 mm. In particular, filler particles that are within the aforementioned particle size range can provide a complete thermal conductive path. In addition, in this embodiment, the ratio of the content of the first filler particles to the content of the second filler particles may be greater than or equal to 0.4 and less than or equal to 0.6. The first filler particles and the second filler particles configured in the aforementioned ratio can enhance the insulation property of the first heat dissipation element 300A and avoid electrical interference to the circuit structure CS.

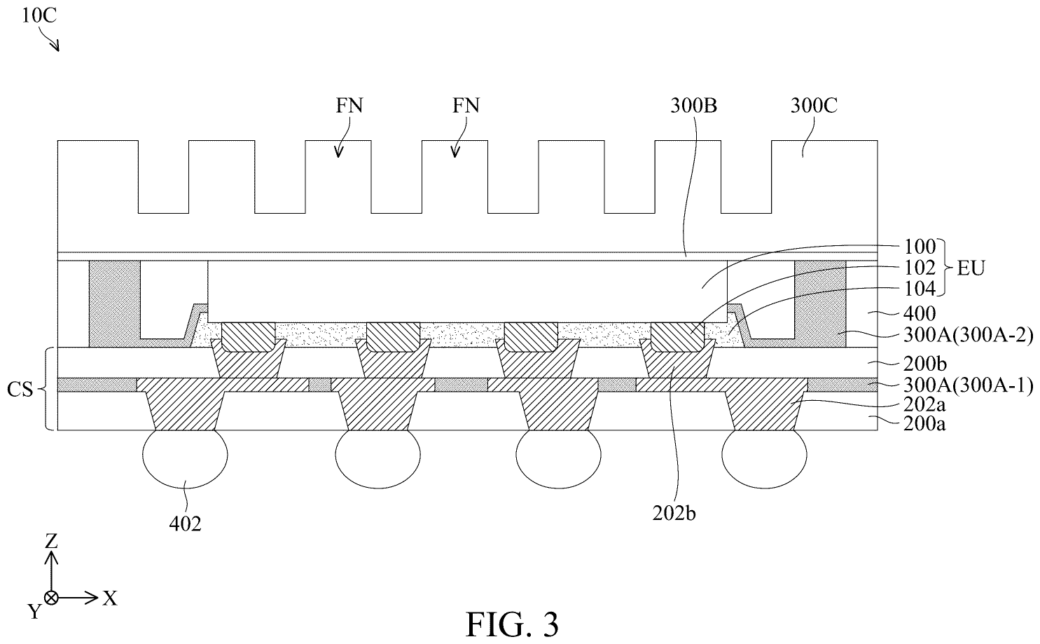

Please refer to FIG. 3, which is a cross-sectional diagram of an electronic device 10C in accordance with some other embodiments of the present disclosure. It should be understood that, for the sake of clarity, some elements of the electronic device 10C may be omitted in the drawings, and only some elements are schematically illustrated. In accordance with some embodiments, additional features may be added to the electronic device 10C described below.

The electronic device 10C shown in FIG. 3 is substantially similar to the electronic device 10A. Compared with the electronic device 10A, the first heat dissipation element 300A (300A-2) disposed in the encapsulation layer 400 of the electronic device 10C further extends onto the side surface of the insulating layer 104. The first heat dissipation element 300A (300A-2) is in contact with the electronic unit EU. Specifically, in this embodiment, the first heat dissipation element 300A-2 extends from the top surface to the bottom surface of the encapsulation layer 400, and further extends onto the conductive layer 202b and the side surface and a portion of the top surface of and the insulating layer 104. The first heat dissipation element 300A-2 may be conformally disposed on the side surface and a portion of the top surface of the insulating layer 104. Similarly, in this embodiment, the heat transfer coefficient of the first heat dissipation element 300A-2 is greater than the heat transfer coefficient of the insulating layer 200b and less than the heat transfer coefficient of the conductive layer 202a. The coefficient of thermal expansion of the first heat dissipation element 300A-2 is greater than the coefficient of thermal expansion of the insulating layer 200b and less than the coefficient of thermal expansion of the conductive layer 202a. Specifically, in this embodiment, the heat transfer coefficient of the first heat dissipation element 300A-2 may be greater than or equal to 3 W/mK and less than or equal to 50 W/mK, and the coefficient of thermal expansion of the first heat dissipation element 300A-2 may be greater than or equal to 3 ppm/° C. and less than or equal to 15 ppm/° C. Furthermore, the ratio of the coefficient of thermal expansion of the first heat dissipation element 300A-2 to the coefficient of thermal expansion of the insulating layer 200a or the insulating layer 200b may be between 0.8 and 4. In addition, in this embodiment, the solid content of the first heat dissipation element 300A-2 may be between 60 wt % and 90 wt %, and the particle size of the filler particles of the first heat dissipation element 300A-2 may be between 0.02 mm and 50 mm. In particular, filler particles that are within the aforementioned particle size range can provide a complete thermal conductive path. In addition, in this embodiment, the ratio of the content of the first filler particles to the content of the second filler particles may be greater than or equal to 0.2 and less than or equal to 0.4. The first filler particles and the second filler particles configured in the aforementioned ratio can improve the insulation property of the first heat dissipation element 300A-2 and avoid electrical interference to the circuit structure CS.

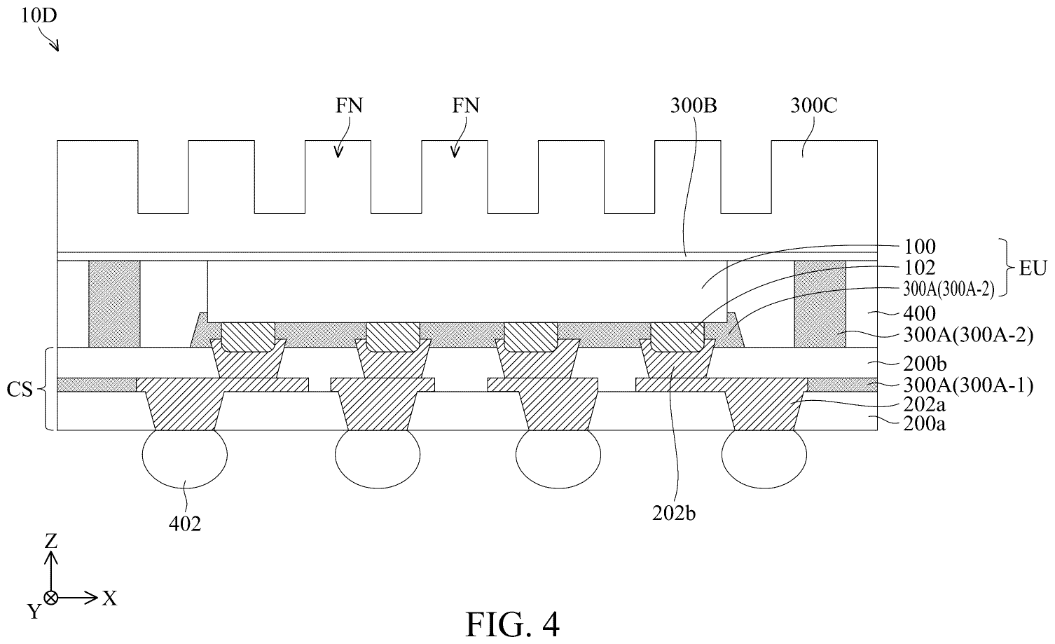

Please refer to FIG. 4, which is a cross-sectional diagram of an electronic device 10D in accordance with some other embodiments of the present disclosure. It should be understood that, for the sake of clarity, some elements of the electronic device 10D may be omitted in the drawings, and only some elements are schematically illustrated. In accordance with some embodiments, additional features may be added to the electronic device 10D described below.

The electronic device 10D shown in FIG. 4 is substantially similar to the electronic device 10B. Compared with the electronic device 10B, the insulating layer 104 in the electronic device 10D is replaced by the first heat dissipation element 300A (300A-2). In this embodiment, the first heat dissipation element 300A-2 is used as a filling material disposed between the circuit structure CS and the chip 100, and the first heat dissipation element 300A (300A-2) is in contact with the electronic unit EU. The first heat dissipation element 300A-2 may contact the chip 100, the conducting pad 102, the conductive layer 202b, and the insulating layer 200b. Similarly, in this embodiment, the heat transfer coefficient of the first heat dissipation element 300A-2 is greater than the heat transfer coefficient of the insulating layer 200b and less than the heat transfer coefficient of the conductive layer 202a. The coefficient of thermal expansion of the first heat dissipation element 300A-2 is greater than the coefficient of thermal expansion of the insulating layer 200b and less than the coefficient of thermal expansion of the conductive layer 202a. Specifically, in this embodiment, the heat transfer coefficient of the first heat dissipation element 300A-2 may be greater than or equal to 3 W/mK and less than or equal to 50 W/mK, and the coefficient of thermal expansion of the first heat dissipation element 300A-2 may be greater than or equal to 3 ppm/° C. and less than or equal to 15 ppm/° C. Furthermore, the ratio of the coefficient of thermal expansion of the first heat dissipation element 300A-2 to the coefficient of thermal expansion of the insulating layer 200a or the insulating layer 200b may be between 0.8 and 4. In addition, in this embodiment, the solid content of the first heat dissipation element 300A-2 may be between 60 wt % and 90 wt %, and the particle size of the filler particles of the first heat dissipation element 300A-2 may be between 0.02 mm and 50 mm. In particular, filler particles that are within the aforementioned particle size range can provide a complete thermal conductive path. In addition, in this embodiment, the ratio of the content of the first filler particles to the content of the second filler particles may be greater than or equal to 0.2 and less than or equal to 0.4. The first filler particles and the second filler particles configured in the aforementioned ratio can improve the insulation property of the first heat dissipation element 300A-2 and avoid electrical interference to the circuit structure CS.

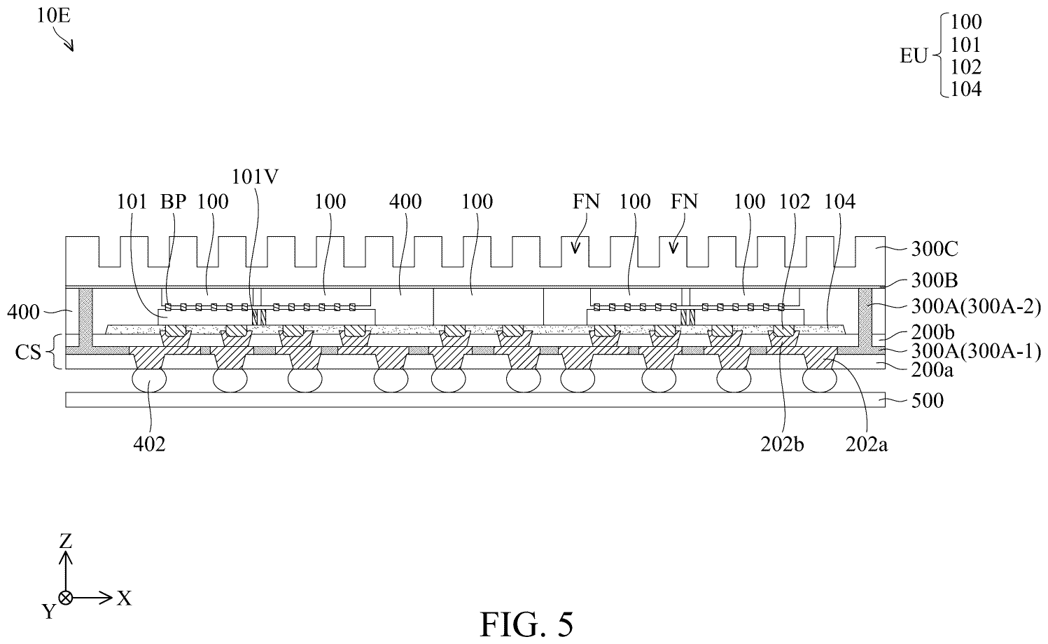

Next, please refer to FIG. 5, which is a cross-sectional diagram of an electronic device 10E in accordance with some other embodiments of the present disclosure. It should be understood that, for the sake of clarity, some elements of the electronic device 10E may be omitted in the drawings, and only some elements are schematically illustrated. In accordance with some embodiments, additional features may be added to the electronic device 10E described below.

The electronic device 10E shown in FIG. 5 is a packaging structure including a plurality of electronic units EU. The plurality of electronic units EU may have chips 100 of the same or different types. In this embodiment, parts of the chips 100 may be first disposed on a substrate 101. The substrate 101 may be a through-glass-via (TGV) substrate having a through hole 101V. The substrate 101 may serve as an interposer substrate. Parts of the chips 100 may be bonded to the substrate 101 through a connection element BP. The connection element BP may include, for example, a conductive bump, but it is not limited thereto. Furthermore, the substrate 101 may be further electrically connected to the connection element 402 through the conducting pad 102 and the circuit structure CS, and may be further electrically connected to an external electronic component 500 through the connection element 402. In accordance with some embodiments, the electronic component 500 may include a printed circuit board (PCB), but the present disclosure is not limited thereto.

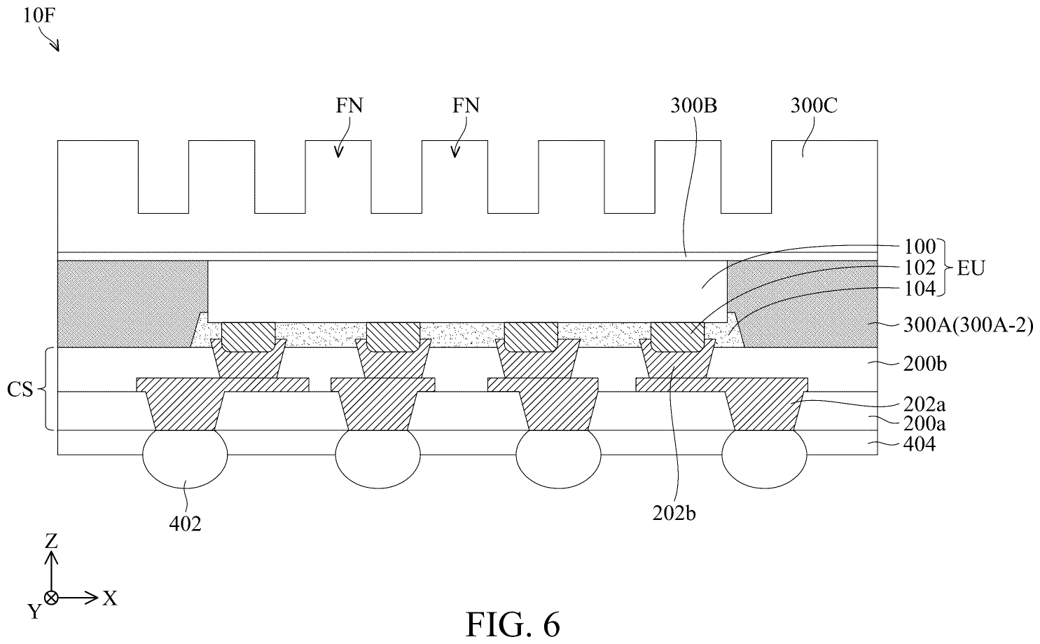

Please refer to FIG. 6, which is a cross-sectional diagram of an electronic device 10F in accordance with some other embodiments of the present disclosure. It should be understood that, for the sake of clarity, some elements of the electronic device 10F may be omitted in the drawings, and only some elements are schematically illustrated. In accordance with some embodiments, additional features may be added to the electronic device 10F described below.

The electronic device 10F shown in FIG. 6 is substantially similar to the electronic device 10A. Compared with the electronic device 10A, the encapsulation layer 400 of the electronic device 10F is replaced by the first heat dissipation element 300A (300A-2), and the electronic device 10F may not have the first heat dissipation element 300A disposed in the circuit structure CS. In this embodiment, the first heat dissipation element 300A-2 is used as the encapsulation layer 400, and the first heat dissipation element 300A (300A-2) is in contact with the electronic unit EU. The first heat dissipation element 300A-2 can be connected may contact the chip 100, the conducting pad 102 and the insulating layer 200b. In this embodiment, the heat transfer coefficient of the first heat dissipation element 300A-2 is greater than the heat transfer coefficient of the insulating layer 200b and less than the heat transfer coefficient of the conductive layer 202a. The coefficient of thermal expansion of the first heat dissipation element 300A-2 is greater than the coefficient of thermal expansion of the insulating layer 200b and less than the coefficient of thermal expansion of the conductive layer 202a. Specifically, in this embodiment, the heat transfer coefficient of the first heat dissipation element 300A-2 may be greater than or equal to 3 W/mK and less than or equal to 50 W/mK, and the coefficient of thermal expansion of the first heat dissipation element 300A-2 may be greater than or equal to 3 ppm/° C. and less than or equal to 15 ppm/° C. Furthermore, the ratio of the coefficient of thermal expansion of the first heat dissipation element 300A-2 to the coefficient of thermal expansion of the insulating layer 200a or the insulating layer 200b may be between 0.8 and 4. In addition, in this embodiment, the solid content of the first heat dissipation element 300A-2 may be between 60 wt % and 90 wt %, and the particle size of the filler particles of the first heat dissipation element 300A-2 may be between 0.02 mm and 50 mm. In particular, filler particles that are within the aforementioned particle size range can provide a complete thermal conductive path. In addition, in this embodiment, the ratio of the content of the first filler particles to the content of the second filler particles may be greater than or equal to 0.2 and less than or equal to 0.4. The first filler particles and the second filler particles configured in the aforementioned ratio can improve the insulation property of the first heat dissipation element 300A-2 and avoid electrical interference to the circuit structure CS.

In addition, the electronic device 10F may further include a buffer layer 404 disposed on the surface of the insulating layer 200a. The buffer layer 404 may contact the insulating layer 200a and the connection element 402. The connection element 402 may pass through the buffer layer 404. The buffer layer 404 can absorb stress and protect the electronic device 10F. In accordance with some embodiments, the buffer layer 404 may include a single layer or multiple layers. In accordance with some embodiments, the buffer layer 404 may include a polymer insulating material, such as Ajinomoto Build-up Film (ABF), polybenzoxazole (PBO), polyimide, photosensitive polyimide (PSPI), benzocyclobutene (BCB), epoxy resin, another suitable buffer material or a combination thereof, but it is not limited thereto.

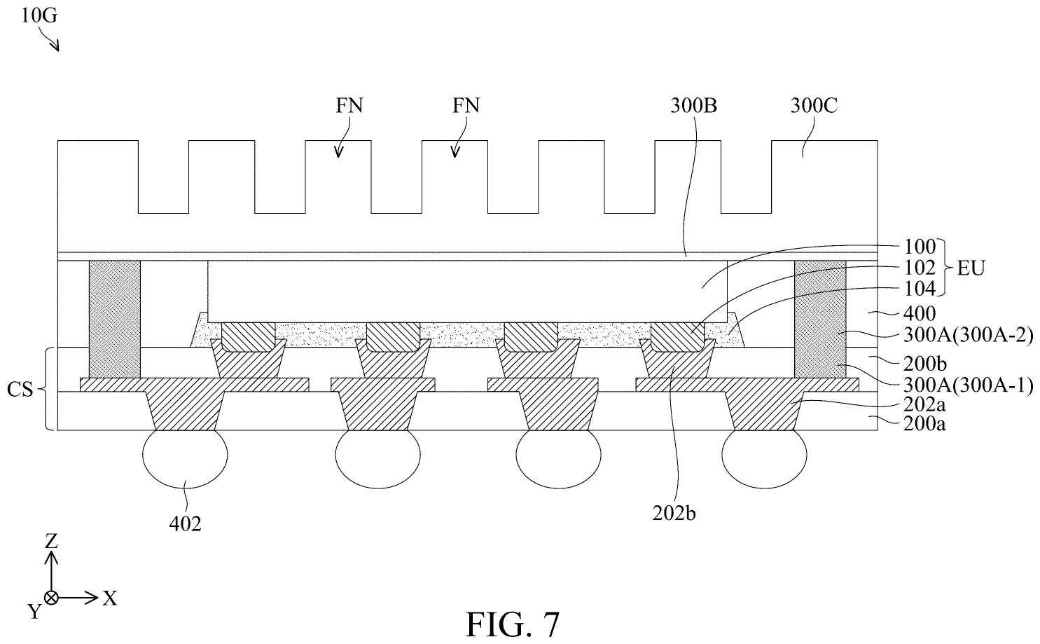

Please refer to FIG. 7, which is a cross-sectional diagram of an electronic device 10G in accordance with some other embodiments of the present disclosure. It should be understood that, for the sake of clarity, some components of the electronic device 10G may be omitted in the drawings, and only some components are schematically illustrated. In accordance with some embodiments, additional features may be added to the electronic device 10G described below.

The electronic device 10G shown in FIG. 7 is substantially similar to the electronic device 10A. Compared with the electronic device 10A, the first heat dissipation element 300A (300A-2) of the electronic device 10G extends from the top surface of the encapsulation layer 400 to the conductive layer 202a of the circuit structure CS (the first heat dissipation element 300A disposed in the circuit structure CS is also labeled 300A-1). In this embodiment, the first heat dissipation element 300A-1 may contact the conductive layer 202a. The first heat dissipation element 300A-2 may contact the second heat dissipation element 300B, the encapsulation layer 400, and the insulating layer 200b. In this embodiment, the heat transfer coefficient of the first heat dissipation element 300A (300A-1 and 300A-2) is greater than the heat transfer coefficient of the insulating layer 200b and less than the heat transfer coefficient of the conductive layer 202a. The coefficient of thermal expansion of the first heat dissipation element 300A (300A-1 and 300A-2) is greater than the coefficient of thermal expansion of the insulating layer 200b and less than the coefficient of thermal expansion of the conductive layer 202a. Specifically, in this embodiment, the heat transfer coefficient of the first heat dissipation element 300A (300A-1 and 300A-2) may be greater than or equal to 3 W/mK and less than or equal to 50 W/mK, and the coefficient of thermal expansion of the first heat dissipation element 300A may be greater than or equal to 3 ppm/° C. and less than or equal to 15 ppm/° C. Furthermore, the ratio of the coefficient of thermal expansion of the first heat dissipation element 300A to the coefficient of thermal expansion of the insulating layer 200a or the insulating layer 200b may be between 0.8 and 4. In addition, in this embodiment, the solid content of the first heat dissipation element 300A may be between 60 wt % and 90 wt %, and the particle size of the filler particles of the first heat dissipation element 300A may be between 0.02 mm and 50 mm. In particular, filler particles that are within the aforementioned particle size range can provide a complete thermal conductive path. In addition, in this embodiment, the ratio of the content of the first filler particles to the content of the second filler particles may be greater than or equal to 0.2 and less than or equal to 0.4. The first filler particles and the second filler particles configured in the aforementioned ratio can enhance the insulation property of the first heat dissipation element 300A (300A-1 and 300A-2) and avoid electrical interference to the circuit structure CS.

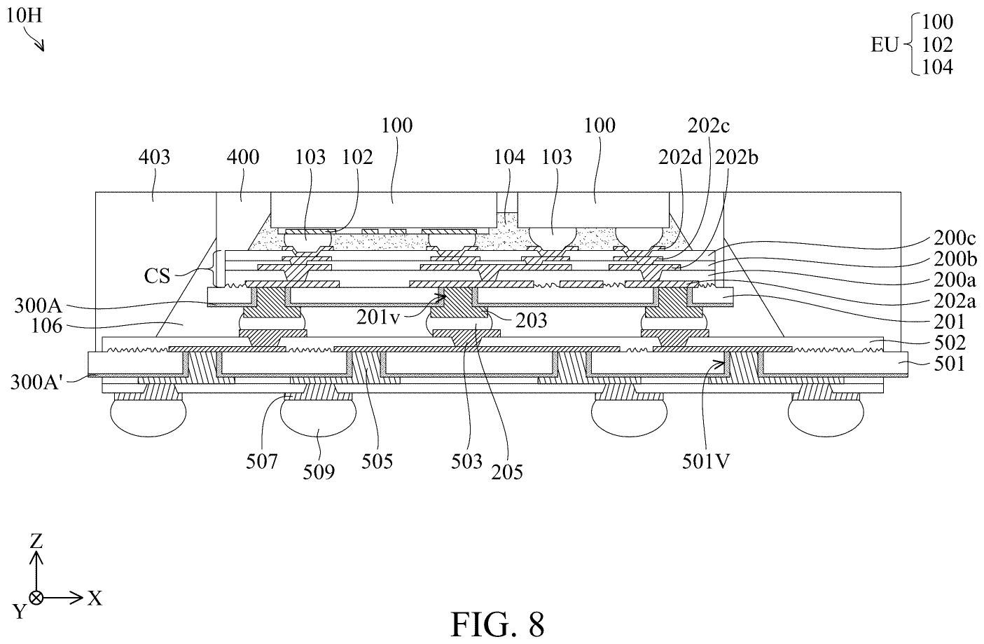

Please refer to FIG. 8, which is a cross-sectional diagram of an electronic device 10H in accordance with some other embodiments of the present disclosure. It should be understood that, for the sake of clarity, some components of the electronic device 10H may be omitted in the drawings, and only some components are schematically illustrated. In accordance with some embodiments, additional features may be added to the electronic device 10H described below.

The electronic device 10H shown in FIG. 8 is a packaging structure including a plurality of electronic units EU. The plurality of electronic units EU may have chips 100 of the same or different types. In this embodiment, the electronic units EU may be first disposed on a substrate 201. The substrate 201 may be a through-glass-via (TGV) substrate having a through hole 201V. The substrate 201 may serve as an interposer substrate. The chips 100 may be electrically connected to the circuit structure CS through a connection element 103. The circuit structure CS may include a conductive layer 202a, an insulating layer 200a, a conductive layer 202b, an insulating layer 200b, a conductive layer 202c, an insulating layer 200c, and a conductive layer 202d stacked in a direction parallel to the normal direction of the electronic unit EU. Furthermore, the electronic device 10H may further include an insulating layer 106, and the insulating layer 106 may contact the encapsulation layer 400, the substrate 201, and an insulating layer 502. The insulating layer 106 may be used as a filling material. The material of the insulating layer 106 is the same as or similar to the material of the insulating layer 104. In addition, the electronic device 10H may further include an encapsulation layer 403. The encapsulation layer 403 may surround the encapsulation layer 400 and the insulating layer 106 and contact the encapsulation layer 400 and the insulating layer 106. The encapsulation layer 403 may reduce the impact of water and oxygen in the external environment on the packaging structure. The material of the encapsulation layer 403 is the same as or similar to that of the encapsulation layer 400.

Furthermore, the circuit structure CS may be electrically connected to the conductive element (not illustrated) on the substrate 501 through a conductive element 203 disposed in the through hole 201V, a connection element 205 and a contact pad 503. In detail, the contact pad 503 may penetrate the insulating layer 502 to be electrically connected to the conductive element on the substrate 501. The substrate 501 may also be a through-glass substrate having a through hole 501V. The circuit structure CS may be electrically connected to a connection element 509 through a conductive element 505 disposed in the through hole 501V and a conducting pad 507.

It should be noted that in this embodiment, the first heat dissipation element 300A is disposed on the side surface of the through hole 201V of the substrate 201 and extend on the surface of the substrate 201 (for example, the side of the substrate 201 away from the circuit structure CS), and another first heat dissipation element 300A′ is disposed on the side surface of the through hole 501V of the substrate 501 and extend on the surface of the substrate 501 (for example, the side of the substrate 501 away from the circuit structure CS).

Moreover, in accordance with some embodiments, portions of the surfaces of the substrate 201 and the substrate 501 may be roughened. For example, the substrate 201 has a roughened surface on the side close to the circuit structure CS, and the substrate 501 has a roughened surface on the side close to the circuit structure CS, thereby enhancing the bonding strength between the substrate and other films/layers. Furthermore, in accordance with some embodiments, the roughness of the surface layer of the circuit structure CS (for example, the insulating layer 200c in FIG. 8) is greater than the roughness of the surface layer of the substrate 201 (for example, the side close to the circuit structure CS) or the roughness of the surface layer of the substrate 501 (for example, the side close to the circuit structure CS), and the roughness of the surface layer of the substrate 201 or the surface layer of the substrate 501 is greater than the roughness of the surface layer of the conductive layer (for example, the conductive layer 202a in FIG. 8).

To summarize the above, the electronic device provided in the embodiments of the present disclosure includes a specific configuration of heat dissipation element, which can enhance the heat dissipation performance of the electronic device (for example, an electronic device having a redistribution structure), thereby improving the reliability and performance of the electronic device.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
an electronic unit; and
a circuit structure electrically connected to the electronic unit, wherein the circuit structure includes a first conductive layer, a first insulating layer and a first heat dissipation element, the first insulating layer is disposed between the first conductive layer and the electronic unit, and the first heat dissipation element is in contact with the first conductive layer,
wherein a heat transfer coefficient of the first heat dissipation element is greater than a heat transfer coefficient of the first insulating layer and less than a heat transfer coefficient of the first conductive layer.

2. The electronic device as claimed in claim 1, wherein a coefficient of thermal expansion of the first heat dissipation element is greater than a coefficient of thermal expansion of the first insulating layer and less than a coefficient of thermal expansion of the first conductive layer.

3. The electronic device as claimed in claim 2, wherein a ratio of the coefficient of thermal expansion of the first heat dissipation element to the coefficient of thermal expansion of the first insulating layer is between 0.8 and 4.

4. The electronic device as claimed in claim 1, further comprising:
an encapsulation layer surrounding the electronic unit.

5. The electronic device as claimed in claim 4, further comprising:
a second heat dissipation element disposed on the encapsulation layer, wherein the electronic unit is disposed between the second heat dissipation element and the circuit structure, and a heat transfer coefficient of the second heat dissipation element is greater than the heat transfer coefficient of the first heat dissipation element.

6. The electronic device as claimed in claim 5, wherein the second heat dissipation element is in contact with the first heat dissipation element.

7. The electronic device as claimed in claim 4, wherein the heat transfer coefficient of the first heat dissipation element is less than or equal to the heat transfer coefficient of the encapsulation layer.

8. The electronic device as claimed in claim 4, further comprising:
another first heat dissipation element disposed in the encapsulation layer and contacting with the first insulating layer.

9. The electronic device as claimed in claim 8, wherein the another first heat dissipation element is in contact with the electronic unit.

10. The electronic device as claimed in claim 9, wherein the another first heat dissipation element penetrates the encapsulation layer.

11. The electronic device as claimed in claim 9, wherein the electronic unit comprises a chip, a conducting pad and a second insulating layer, the chip is electrically connected to the circuit structure through the conducting pad, and the second insulating layer is disposed between the chip and the circuit structure and is in contact with the another first heat dissipation element.

12. The electronic device as claimed in claim 1, wherein the heat transfer coefficient of the first heat dissipation element is greater than or equal to 3 W/mK and less than or equal to 50 W/mK.

13. The electronic device as claimed in claim 2, wherein the coefficient of thermal expansion of the first heat dissipation element is greater than or equal to 5 ppm/° C. and less than or equal to 40 ppm/° C.

14. The electronic device as claimed in claim 5, further comprising:
a third heat dissipation element disposed on the second heat dissipation element and having a plurality of fin structures, wherein a heat transfer coefficient of the third heat dissipation element is greater than that of the first heat dissipation element.

15. The electronic device as claimed in claim 14, wherein the heat transfer coefficient of the second heat dissipation element is less than the heat transfer coefficient of the third heat dissipation element.

16. The electronic device as claimed in claim 1, wherein the first heat dissipation element is disposed in a gap between patterned portions of the first conductive layer and contacts a side of the first conductive layer.

17. The electronic device as claimed in claim 1, wherein an upper surface or a lower surface of the first heat dissipation element is substantially aligned with an upper surface or a lower surface of the first conductive layer.

18. The electronic device as claimed in claim 1, wherein the first heat dissipation element comprises first filler particles with a relatively small heat transfer coefficient and second filler particles with a relatively large heat transfer coefficient.

19. The electronic device as claimed in claim 18, wherein in the first heat dissipation element, a ratio of the content of the first filler particles to the content of the second filler particles is greater than 0 and less than or equal to 0.6.

20. The electronic device as claimed in claim 18, wherein a solid content of the first heat dissipation element is between 20 wt % and 90 wt %.
